(19) United States
(12) Patent Application Publication
(10) Pub. No.: US 2016/0087224 A1
(43) Pub. Date: Mar. 24, 2016

(54) ORGANIC LIGHT-EMITTING DEVICE

(71) Applicant: SAMSUNG DISPLAY CO., LTD., Yongin-City (KR)

(72) Inventors: Younsun KIM, Yongin-City (KR); Seulong KIM, Yongin-City (KR); Dongwoo SHIN, Yongin-City (KR); Jungsub LEE, Yongin-City (KR); Naoyuki ITO, Yongin-City (KR)

(21) Appl. No.: 14/705,388

(22) Filed: May 6, 2015

(30) Foreign Application Priority Data
Sep. 19, 2014 (KR) 10-2014-0125246

(51) Int. Cl. H01L 51/00

(52) U.S. Cl. CPC H01L 51/0072; H01L 51/0073; H01L 51/0061; H01L 51/0062; H01L 51/0074; H01L 51/0094; H01L 51/0056; H01L 51/0052; H01L 2251/5376; H01L 2251/5384; H01L 51/5206

(57) ABSTRACT

An organic light-emitting device includes a first electrode, a second electrode facing the first electrode, and an organic layer disposed between the first electrode and the second electrode and including a dopant, a first host, and a second host.

### CROSS-REFERENCE TO RELATED APPLICATION

Korean Patent Application No. 10-2014-0125246 filed on Sep. 19, 2014, in the Korean Intellectual Property Office, and entitled: “Organic Light-Emitting Device,” is incorporated by reference herein in its entirety.

### BACKGROUND

1. Field

Embodiments relate to an organic light-emitting device.

2. Description of the Related Art

In an organic light-emitting device (OLED), holes supplied from an anode are combined with electrons supplied from a cathode in an organic emission layer formed between the anode and the cathode, thereby generating light. Such an OLED has excellent color reproduction properties, high color purity, high response speeds, self-light emission, small thickness, light-weight properties, a high contrast ratio, a wide viewing angle, a low voltage driving, and low power consumption. Due to these properties, OLEDs are widely used in TVs, PC monitors, mobile communication terminals, MP3 players, and navigation devices for mobile vehicles.

In general, an OLED includes a substrate, an anode, a hole transport layer, an emission layer, an electron transport layer, and a cathode, which are sequentially disposed in this stated order. When a voltage is applied between the anode and the cathode, holes supplied from the anode pass through the hole transport layer to the emission layer, and electrons supplied from the cathode pass through the electron transport layer to the emission layer. In the emission layer, the holes are recombined with the electrons to produce excitons, which then radiatively decay, generating light having a wavelength corresponding to a band gap of a material that constitutes the emission layer.

### SUMMARY

Embodiments are directed to an organic light-emitting device including a first electrode, a second electrode facing the first electrode, and an organic layer disposed between the first electrode and the second electrode and including a dopant, a first host, and a second host.

The dopant is a material that emits delayed fluorescence, the first host includes a compound represented by Formula 1 below, and the second host includes any one of compounds represented by Formula 2-1, Formula 2-2, and Formula 3 below:

in Formula 1, Formula 2-1, Formula 2-2, and Formula 3,

X is N, S, or O, and when X is S or O, a₁ and a₂ are 0,

R₁ to R₃ may be each independently selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof, a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group, —N(Q₁)(Q₂) (Q₁ and Q₂ are each independently a C₆-C₄₀ aryl group), a monovalent C₆-C₄₀ non-aromatic condensed polycyclic group;

a C₁-C₄₀ alkyl group, a C₂-C₄₀ alkenyl group, a C₂-C₄₀ alkynyl group, and a C₁-C₄₀ alkoxy group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group; and

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a monovalent C₆-C₄₀ non-aromatic condensed polycyclic group, a C₆-C₄₀ aryloxy group, and a C₆-C₄₀ arylthio group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group,

a plurality of R₂ and R₃ are independent from each other,

Ar₁ to Ar₁₁ are each independently selected from —N(Q₁)(Q₂) (Q₁ and Q₂ are each independently a C₆-C₄₀ aryl group), a C₆-C₄₀ aryl group, a C₁-C₄₀ heteroaryl group, a monovalent C₆-C₄₀ non-aromatic condensed polycyclic group; —N(Q₁)(Q₂) (Q₁ and Q₂ are each independently a C₆-C₄₀ aryl group), a C₆-C₄₀ aryl group, a C₁-C₄₀ heteroaryl group, and a monovalent C₆-C₄₀ non-aromatic condensed polycyclic group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group,

L₁ to L₈ are each independently selected from a direct bond, —O—, a C₃-C₁₀ cycloalkylene group, a C₆-C₄₀ arylene group, a C₂-C₄₀ heteroarylene group, a divalent C₆-C₄₀ non-aromatic condensed polycyclic group; a C₃-C₁₀ cycloalkylene group, a C₆-C₄₀ arylene group, a C₂-C₄₀ heteroarylene group, and a divalent C₆-C₄₀ non-aromatic condensed polycyclic group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group,

a plurality of L₁ to L₈ are independent from each other, and when L₄ and L₅ are each a direct bond, Ar₃ and Ar₄ may be linked to each other to form a condensed cyclic ring,

a₁, b₁, and c₁ are an integer selected from 0, 1, 2, and 3,

a₂ is 0 or 1, and b₂ and c₂ are each 1 or 2,

b and c are each an integer selected from 0, 1, 2, 3, and 4, and

d to h are each independently an integer selected from 0, 1, 2, and 3.

An amount of the dopant in the emission layer may be in a range of about 0.01 to about 30 parts by weight.

A weight ratio of the first host to the second host is in a range of 20:80 to 80:20.

The organic light-emitting device may further include a hole transport region between the first electrode and the emission layer.

The organic light-emitting device may further include an electron transport region between the second electrode and the emission layer.

### BRIEF DESCRIPTION OF THE DRAWINGS

Features will become apparent to those of skill in the art by describing in detail example embodiments with reference to the attached drawings in which:

FIG. 1 illustrates an energy level diagram to explain a delayed fluorescence of a luminescent material, and

FIG. 2 illustrates a schematic view of an organic light-emitting device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art.

In the drawing figures, the dimensions of layers and regions may be exaggerated for clarity of illustration. Like reference numerals refer to like elements throughout.

An emission layer of an organic light-emitting device according to an embodiment will now be explained in detail.

The emission layer may include a host and a dopant.

The host includes a first host and a second host.

The first host may includes a compound represented by Formula 1 below, and the second host includes any one of compounds represented by Formula 2-1, Formula 2-2, and Formula 3 below.

in Formula 1, Formula 2-1, Formula 2-2, and Formula 3,

when X is N, S, or O, or when X is S or O, a₁ and a₂ are 0,

R₁ to R₃ may be each independently selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof, a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group, —N(Q₁)(Q₂) (Q₁ and Q₂ are each independently a C₆-C₄₀ aryl group), a monovalent C₆-C₄₀ non-aromatic condensed polycyclic group;

a C₁-C₄₀ alkyl group, a C₂-C₄₀ alkenyl group, a C₂-C₄₀ alkynyl group, and a C₁-C₄₀ alkoxy group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group; and

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a monovalent C₆-C₄₀ non-aromatic condensed polycyclic group, a C₆-C₄₀ aryloxy group, and a C₆-C₄₀ arylthio group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group,

a plurality of R₂ and R₃ are independent from each other,

Ar₁ to Ar₁₁ are each independently selected from —N(Q₁)(Q₂) (Q₁ and Q₂ are each independently a C₆-C₄₀ aryl group), a C₆-C₄₀ aryl group, a C₂-C₄₀ heteroaryl group, a monovalent C₆-C₄₀ non-aromatic condensed polycyclic group; —N(Q₁)(Q₂) (Q₁ and Q₂ are each independently a C₆-C₄₀ aryl group), a C₆-C₄₀ aryl group, a C₁-C₄₀ heteroaryl group, and a monovalent C₆-C₄₀ non-aromatic condensed polycyclic group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group,

L₁ to L₈ are each independently selected from a direct bond, —O—, a C₃-C₁₀ cycloalkylene group, a C₆-C₄₀ arylene group, a C₂-C₄₀ heteroarylene group, a divalent C₆-C₄₀ non-aromatic condensed polycyclic group; a C₃-C₁₀ cycloalkylene group, a C₆-C₄₀ arylene group, a C₂-C₄₀ heteroarylene group, and a divalent C₆-C₄₀ non-aromatic condensed polycyclic group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₆ heteroaryl group, a C₆-C₄₀ aryloxy group, and a C₆-C₄₀ arylthio group,

a plurality of L₁ to L₈ are independent from each other, and when L₄ and L₅ are each a direct bond, Ar₃ and Ar₄ may be linked to each other to form a condensed cyclic ring,

a₁, b₁, and c₁ are an integer selected from 0, 1, 2, and 3,

a₂ is 0 or 1, and b₂ and c₂ are each 1 or 2,

b and c are each an integer selected from 0, 1, 2, 3, and 4, and

d to h are each independently an integer selected from 0, 1, 2, and 3.

R₁ to R₃ may be each independently selected from a methyl group, an ethyl group, a propyl group, a butyl group, a pentyl group, a hexyl group, a heptyl group, a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran, an indolyl group, an isoindolyl group, an indolizinyl group, a benzofuryl group, an isobenzofuryl group, an indazolyl group, a benzimidazolyl group, a benzoxazolyl group, a benzisoxazolyl group, an imidazopyridyl group, a purinyl group, a quinolyl group, isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, a pyridoindolyl group, a dibenzofuryl group, a phenanthridinyl group, a benzoquinolyl group, a phenazinyl group, a dibenzosilolyl group, a dibenzothiophenyl group, a benzocarbazole group, —N(Q₁)(Q₂) (Q₁ and Q₂ are each independently a C₆-C₄₀ aryl group);

a methyl group, an ethyl group, a propyl group, a butyl group, a pentyl group, a hexyl group, a heptyl group, an octyl group, a nonyl group, and a decyl group, each substituted with at least one selected from a deuterium, a halogen atom, a hydroxyl group, a cyano group, a nitro group, and an amino group; and

a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran, an indolyl group, an isoindolyl group, an indolizinyl group, benzofuryl group, isobenzofuryl group, an indazolyl group, benzimidazolyl group, benzoxazolyl group, benzisoxazolyl group, imidazopyridyl group, a purinyl group, a quinolyl group, isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, pyridoindolyl group, dibenzofuryl group, a phenanthridinyl group, benzoquinolyl group, a phenazinyl group, a dibenzosilolyl group, a dibenzothiophenyl group, and a benzocarbazole group, each substituted with at least one selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₁₀ alkyl group, a C₂-C₁₀ alkenyl group, a C₂-C₁₀ alkynyl group, a C₁-C₁₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₃₀ aryl group, a C₁-C₃₀ heteroaryl group, a C₆-C₃₀ aryloxy group, a C₆-C₃₀ arylthio group and —Si(Q₃₁)(Q₃₂)(Q₃₃) (herein Q₃₁ to Q₃₃ are each independently selected from a hydrogen, a C₁-C₁₀ alkyl group, a C₁-C₁₀ alkoxy group, and a C₆-C₂₀ aryl group).

In detail, R₁ and R₃ may each be independently represented by any one of Formulae 4A to 4H below:

in Formulae 4A to 4H,

Z₁₁ to Z₁₆ may be each independently selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, and a C₁-C₄₀ heteroaryl group;

a C₁-C₂₀ alkyl group and a C₁-C₂₀ alkoxy group, each substituted with at least one selected from a deuterium and a halogen atom; and

a C₆-C₄₀ aryl group and a C₁-C₄₀ heteroaryl group, each substituted with at least one selected from a deuterium, a halogen atom, a C₁-C₂₀ alkyl group, a C₁-C₂₀ alkoxy group, a C₆-C₂₀ aryl group, and a C₁-C₂₀ heteroaryl group;

p1 to p3 may be each independently an integer selected from 0, 1, 2, 3, and 4, and

* indicates a binding site.

In some embodiments, Z₁₁ to Z₁₆ may each independently include a cyano group, a methyl group, an ethyl group, a t-butyl group, a phenyl group, or a naphthyl group.

In some embodiments, R₁ to R₃ may be each independently selected from Formulae 5A to 5J below.

* indicates a binding site.

L₁ to L₆ may be each independently selected from —O—, a cyclobutylene, adamantylene, phenylene, pentalenylene, indenylene, naphthylene, azulenylene, heptalenylene, indacenylene, acenaphthylene, fluorenylene, spiro-fluorenylene, benzofluorenylene, dibenzofluorenylene, phenalenylene, phenanthrenylene, anthracenylene, fluoranthenylene, triphenylenylene, pyrenylene, chrysenylene, naphthacenylene, picenylene, perylenylene, pentaphenylene, hexacenylene, pentacenylene, rubicenylene, coronenylene, ovalenylene, pyrrolylene, thiophenylene, furanylene, imidazolylene, pyrazolylene, thiazolylene, isothiazolylene, oxazolylene, isoxazolylene, pyridylene, pyrazinylene, pyrimidinylene, pyridazinylene, isoindolylene, indolylene, indazolylene, purinylene, quinolinylene, isoquinolinylene, benzoquinolinylene, phthalazinylene, naphthyridinylene, quinoxalinylene, quinazolinylene, cinnolinylene, carbazolylene, phenanthridinylene, acridinylene, phenanthrolinylene, phenazinylene, benzoimidazolylene, benzofuranylene, benzothiophenylene, isobenzothiazolylene, benzooxazolylene, isobenzooxazolylene, triazolylene tetrazolylene, oxadiazolylene, triazinylene, dibenzofuranylene, dibenzothiophenylene, benzocarbazolylene, dibenzocarbazolylene, thiadiazolylene, and imidazopyridylene; and

phenylene, pentalenylene, indenylene, naphthylene, azulenylene, heptalenylene, indacenylene, acenaphthylene, fluorenylene, spiro-fluorenylene, benzofluorenylene, dibenzofluorenylene, phenalenylene, phenanthrenylene, anthracenylene, fluoranthenylene, triphenylenylene, pyrenylene, chrysenylene, naphthacenylene, picenylene, perylenylene, pentaphenylene, hexacenylene, pentacenylene, rubicenylene, coronenylene, ovalenylene, pyrrolylene, thiophenylene, furanylene, imidazolylene, pyrazolylene, thiazolylene, isothiazolylene, oxazolylene, isoxazolylene, pyridylene, pyrazinylene, pyrimidinylene, pyridazinylene, isoindolylene, indolylene, indazolylene, furinylene, quinolinylene, isoquinolinylene, benzoquinolinylene, phthalazinylene, naphthyridinylene, quinoxalinylene, quinazolinylene, cinnolinylene, carbazolylene, phenanthridinylene, acridinylene, phenanthrolinylene, phenazinylene, benzoimidazolylene, benzofuranylene, benzothiophenylene, isobenzothiazolylene, benzoxazolylene, isobenzoxazolylene, triazolylene, tetrazolylene, oxadiazolylene, triazinylene, dibenzofuranylene, dibenzothiophenylene, benzocarbazolylene, dibenzocarbazolylene, thiadiazolylene, and imidazopyridylene, each substituted with at least one selected from a deuterium, a halogen atom, a hydroxyl group, a cyano group, an amino group, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group.

In detail, L₁ to L₆ may each be independently represented by any one of Formulae 6A to 6I below:

in Formulae 6A to 6I,

Z₂₁ to Z₃₀ may be each independently selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, a C₁-C₄₀ heteroaryl group, a monovalent C₆-C₄₀ non-aromatic condensed polycyclic group, and —Si(Q₃)(Q₄)(Q₅) (Q₃ to Q₅ are each independently a C₆-C₄₀ aryl group);

a C₁-C₂₀ alkyl group and a C₁-C₂₀ alkoxy group, each substituted with at least one selected from a deuterium and a halogen atom; and

a C₆-C₄₀ aryl group and a C₁-C₄₀ heteroaryl group, each substituted with at least one selected from a deuterium, a halogen atom, a C₁-C₂₀ alkyl group, a C₁-C₂₀ alkoxy group, a C₆-C₂₀ aryl group, and a C₁-C₂₀ heteroaryl group;

q1 is an integer selected from 0, 1, 2, 3, and 4;

q2 is an integer selected from 0, 1, 2, and 3;

q3 is an integer selected from 0, 1, and 2;

q4 and q5 are integers selected from 0, 1, 2, and 3;

q6 and q7 are integers selected from 0, 1, 2, 3, 4, and 5, and

* indicates a binding site.

In some embodiments, Z₂₁ to Z₃₀ may include each independently a methyl group, a triphenylsilyl group, or a triphenylmethyl group.

In some embodiments, L₁ to L₆ may each independently be selected from —O— and Formulae 7A to 7P below.

* indicates a binding site.

Ar₁ to Ar₁₁ may be each independently selected from a hydrogen atom, a methyl group, an ethyl group, a propyl group, a butyl group, a pentyl group, a hexyl group, a heptyl group, an octyl group, a nonyl group, a decyl group, a phenyl group, a pentalenyl group, an indenyl group, a naphthyl group, an azulenyl group, an indacenyl group, an acenaphthyl group, a biphenyl group, a heptalenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran, an indolyl group, an isoindolyl group, an indolizinyl group, benzofuryl group, isobenzofuryl group, an indazolyl group, a benzimidazolyl group, a benzoxazolyl group, a benzisoxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, pyridoindolyl group, dibenzofuryl group, a phenanthridinyl group, a benzoquinolyl group, a phenazinyl group, a dibenzosilolyl group, a dibenzothiophenyl group, a benzocarbazole group, and —N(Q₁)(Q₂) (Q₁ and Q₂ are each independently a C₆-C₄₀ aryl group);

a methyl group, an ethyl group, a propyl group, a butyl group, a pentyl group, a hexyl group, a heptyl group, an octyl group, a nonyl group, and a decyl group, each substituted with at least one selected from a deuterium, a halogen atom, a hydroxyl group, a cyano group, a nitro group, and an amino group; and

a phenyl group, a pentalenyl group, an indenyl group, a naphthyl group, an azulenyl group, an indacenyl group, an acenaphthyl group, a biphenyl group, a heptalenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran, an indolyl group, an isoindolyl group, an indolizinyl group, benzofuryl group, isobenzofuryl group, an indazolyl group, a benzimidazolyl group, a benzoxazolyl group, a benzisoxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, pyridoindolyl group, dibenzofuryl group, a phenanthridinyl group, a benzoquinolyl group, a phenazinyl group, a dibenzosilolyl group, a dibenzothiophenyl group, and a benzocarbazole group, each substituted with at least one selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₁₀ alkyl group, a C₂-C₁₀ alkenyl group, a C₂-C₁₀ alkynyl group, a C₁-C₁₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₃₀ aryl group, a C₁-C₃₀ heteroaryl group, a C₆-C₃₀ aryloxy group, a C₆-C₃₀ arylthio group and —Si(Q₃₁)(Q₃₂)(Q₃₃) (herein, Q₃₁ to Q₃₃ are each independently selected from a hydrogen, a C₁-C₁₀ alkyl group, a C₁-C₁₀ alkoxy group, and a C₆-C₂₀ aryl group).

In detail, Ar₁ to Ar₁₁ may be each independently selected from —N(Q₁)(Q₂) (Q₁ and Q₂ are each independently a C₆-C₄₀ aryl group), and Formulae 8A to 8H below.

In Formulae 8A to 8H,

Z₃₁ to Z₃₆ may be each independently selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, a C₁-C₄₀ heteroaryl group, a monovalent C₆-C₄₀ non-aromatic condensed polycyclic group, and Si(Q₃)(Q₄)(Q₅) (Q₃ to Q₅ are each independently a C₆-C₄₀ aryl group);

a C₁-C₂₀ alkyl group and a C₁-C₂₀ alkoxy group, each substituted with at least one selected from a deuterium and a halogen atom; and

a C₆-C₄₀ aryl group and a C₁-C₄₀ heteroaryl group, each substituted with at least one selected from a deuterium, a halogen atom, a C₁-C₂₀ alkyl group, a C₁-C₂₀ alkoxy group, a C₆-C₂₀ aryl group, and a C₁-C₂₀ heteroaryl group;

r1 is an integer selected from 0, 1, 2, 3, 4, and 5,

r2 is an integer selected from 0, 1, 2, and 3,

r3 is an integer selected from 0, 1, 2, 3, and 4,

r4 is 0 or 2,

r5 is an integer selected from 0, 1, 2, 3, 4, and 5, and

* indicates a binding site.

In some embodiments, Z₃₁ to Z₃₆ may include each independently a methyl group, a t-butyl group, or a carbazolyl group.

In some embodiments, Ar₁ to Ar₁₁ may be each independently selected from a diphenylamino group, and Formulae 9A to 9J below.

in Formulae 9A to 9J, * indicates a binding site.

The condensed cyclic compound represented by Formula 1 may be one of compounds illustrated below.

The condensed cyclic compound represented by Formula 2-1 may be one of compounds illustrated below.

The condensed cyclic compound represented by Formula 2-2 may be one of compounds illustrated below.

The condensed cyclic compound represented by Formula 3 may be one of compounds illustrated below.

A weight ratio of the first host to the second host may be in a range of 10:90 to 90:10. An amount of the dopant in the emission layer may be in a range of about 0.01 to about 30 parts by weight.

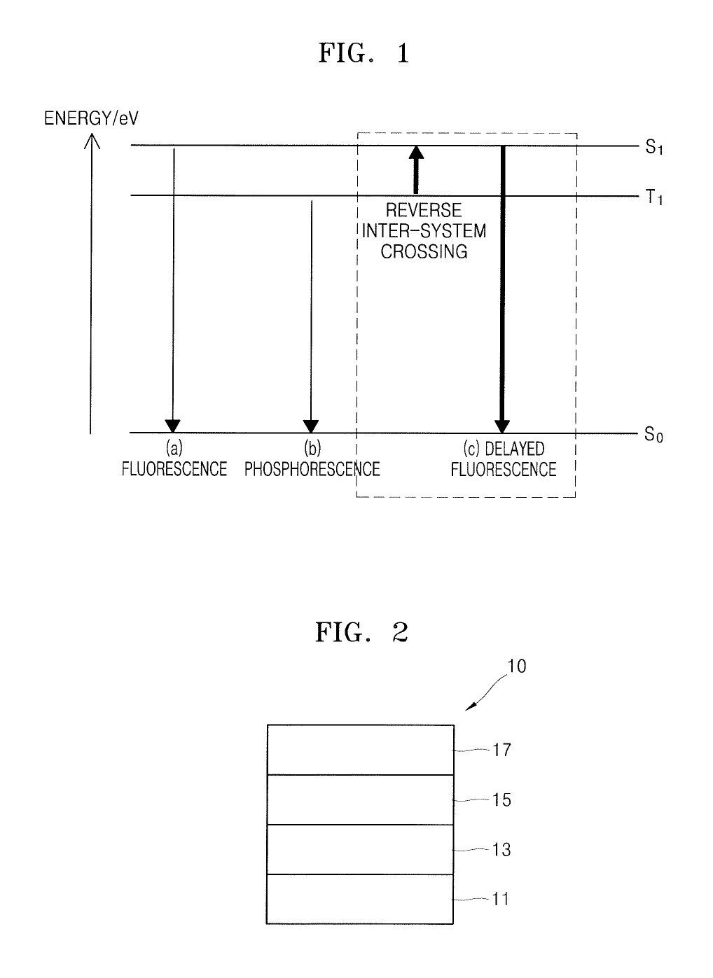

FIG. 1 illustrates an energy level diagram showing a ground state energy level S₀, a triplet energy level T₁, and a singlet energy level S₁ of a luminescent material. In FIG. 1, (a) indicates fluorescent emission occurring when the singlet energy level S is converted into a ground state energy level S₀, while energy is lost in the form of light; (b) indicates phosphorescent emission occurring when the triplet energy level T₁ is converted into the ground state energy level S₀, while energy is lost in the form of light; and (c) indicates delayed fluorescent emission occurring when the singlet energy level S₁, which is populated by an upconversion energy transfer (reverse inter-system crossing) from the triplet energy level T₁ to the singlet energy level S₁, is converted into the ground state energy level S₀.

The dopant may be any one of compounds represented by Formula 3-1, Formula 3-2, Formula 3-3. and Formula 3-4.

[EDG]ₘ-{Aₙ-[EWG]ₒ}ₚ <Formula 3-1>

[EWG]_{q}-{Aᵣ-[EDG]ₛ}ₜ <Formula 3-2>

[EWG]-A-[EDG]-B-[EWG] <Formula 3-3>

[EDG]-A-[EWG]-B-[EDG] <Formula 3-4>

An electron donating group (EDG) includes a functional group that provides an electron donation effect due to an electron pair in a it orbital or an unshared electron pair. EDG may include —C═C—R, —O—R, —N(R)H, —N(R)₂, —NH₂, —OH, —NH(CO)—R, a C₆-C₃₀ aryl group, a substituted or unsubstituted monovalent C₆-C₃₀ non-aromatic condensed polycyclic group, a furanyl group or a derivative thereof, a benzofuranyl group or a derivative thereof, a dibenzofuranyl group or a derivative thereof, a thiophenyl group or a derivative thereof, a benzothiophenyl group or a derivative thereof, a dibenzothiophenyl group or a derivative thereof, a fluorenyl group or a derivative thereof, a spiro fluorenyl group or a derivative thereof, or an indenyl group or a derivative thereof. In some embodiments, EDG may include a substituted or unsubstituted C₁-C₂₀ alkyl group.

An electron withdrawing group (EWG) includes a functional group that provides electron withdrawing effects due to an element having higher electronegativity than carbon, or that forms a partially positive charge. EWG may be an electron transporting group selected from —X (—F, —Cl, —Br, —I), —C(═O)H, —C(═O)—R, —C(═O)O—R, —C(═O)OH, —(C═O)Cl, —CF₃, —S(═O)₂—OH, —S(═O)₂—O—R, —N⁺H₃, —N⁺R₃, —(N⁺═O)═O⁻, a C₂-C₃₀ substituted or unsubstituted N-containing 5-membered group, a C₂-C₃₀ substituted or unsubstituted N-containing 6-membered group, a substituted or unsubstituted N-containing 5-membered group to which a C₁₀-C₃₀ 6-membered ring is fused, and a substituted or unsubstituted N-containing 6-membered group to which a C₁₀-C₃₀ 6-membered ring is fused.

R may be a hydrogen, a deuterium, a C₆-C₃₀ aryl group, a C₁-C₃₀ heteroaryl group; a C₆-C₃₀ aryl group or a C₁-C₃₀ heteroaryl group, each substituted with at least one selected from a C₁-C₁₀ alkyl group, a C₁-C₁₀ alkoxy group, a C₆-C₃₀ aryl group, a C₁-C₃₀ heteroaryl group, a C₆-C₃₀ aryloxy group, and a C₆-C₃₀ arylthio group.

A and B are linking groups that link an EDG to an EWG, and may be, for example, a single bond, a C₁-C₃₀ alkylene, or a C₆-C₃₀ arylene group.

m, q, o, s, p, and t may be an integer selected from 1, 2, 3, 4, 5, 6, 7, 8, 9, and 10, and n and r may be 0 or 1.

Detailed examples of a compound represented by any one of Formulae 3-1 to Formula 3-4 are illustrated below:

The first host represented by Formula 1 may be a host that has a hole transporting unit with a high triplet energy level, and the second host represented by Formula 2-1, Formula 2-2 or Formula 3 may be a host that has an electron transporting unit with a high triplet energy level. The second host represented by Formula 2-1, Formula 2-2 or Formula 3 may have a higher triplet energy level and a higher band gap energy than the first host represented by Formula 1. When a host has a higher triplet energy level, efficiency may be increased. In this case, however, band gap energy may increase together, and thus, injection of charges from adjacent layers may be inefficient and charge transporting characteristics may decrease.

In the present example embodiment, due to high triplet energy of the second host, efficiency may be high, and, due to lower band gap energy of the first host than the band gap energy of the second host, charges may be easily transported.

Hereinafter, an organic light-emitting device including an emission layer will be described in detail.

FIG. 2 illustrates a schematic view of an organic light-emitting device 10 according to an example embodiment.

Referring to FIG. 2, the organic light-emitting device 10 includes a substrate 11, a first electrode 13, an organic layer 15, and a second electrode 17, which are sequentially stacked.

For use as the substrate 11, a suitable substrate that is used in general organic light-emitting devices may be used, and the substrate 11 may be a glass substrate or transparent plastic substrate, each with excellent mechanical strength, thermal stability, transparency, surface smoothness, ease of handling, and water repellency.

The first electrode 13 may be formed by, for example, depositing or sputtering a material for a first electrode on the substrate 11. When the first electrode 13 is an anode, the material for the first electrode may be selected from materials with a high work function to make holes be easily injected. The first electrode 13 may be a transmissive electrode or a reflective electrode. The material for the first electrode 120 may be, for example, a transparent and highly conductive material, and examples of such a material are indium tin oxide (ITO), indium zinc oxide (IZO), tin oxide (SnO), and zinc oxide (ZnO). In some embodiments, magnesium (Mg), silver (Ag), aluminum (Al), aluminum:lithium (Al:Li), potassium (Ca), silver:indium tin oxide (Ag:ITO), magnesium:indium (Mg:In), or magnesium:silver (Mg:Ag) may be used to form a reflective electrode for use as the first electrode 13. The first electrode 13 may have a single-layer structure, or a multi-layer structure including two or more layers. For example, the first electrode 13 may have a three-layered structure of, for example, ITO/Ag/ITO.

The organic layer 15 is disposed on the first electrode 13.

The organic layer 15 may include a hole transport region, an emission layer, and an electron transport region.

The hole transport region may include at least one of a hole injection layer, a hole transport layer, and an electron blocking layer. The electron transport region may include at least one of an electron injection layer, an electron transport layer, and a hole blocking layer.

A hole injection layer (HIL) may be formed on the first electrode 13 by using various methods, such as vacuum deposition, spin coating, casting, Langmuir-Blodgett (LB) deposition, or the like.

When a hole injection layer is formed by vacuum deposition, deposition conditions may vary according to a compound for forming the hole injection layer or a target structure and thermal characteristics of the hole injection layer. The deposition conditions may include, for example, a deposition temperature of about 100 to about 500° C., a vacuum degree of about 10⁻⁸ to about 10⁻³ torr, and a deposition speed of about 0.01 to about 100 Å/sec.

When a hole injection layer is formed by spin coating, coating conditions may vary according to a compound for forming the hole injection layer or a target structure and thermal characteristics of the hole injection layer. For example, a coating speed may be in a range of about 2,000 rpm to about 5,000 rpm, and a temperature for heat treatment for the removal of a solvent after coating may be in a range of about 80° C. to 200° C.

A material for the hole injection layer may be, for example, a suitable hole injection material. Examples of the hole injection material include a phthalocyanine compound, such as copper phthalocyanine, N,N-diphenyl-N,N-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2T-NATA), N,N′-bis(naphthalen-1-yl)-N,N′-bis(phenyl)-2,2′-dimethylbenzidine (α-NPD), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), and (polyaniline)/poly(4-styrenesulfonate) (PANI/PSS).

A thickness of the hole injection layer may be in a range of about 100 Å to about 10,000 Å, for example, about 100 Å to about 1,000 Å. When the thickness of the hole injection layer is within the range described above, the hole injection layer may have satisfactory hole injection characteristics without a substantial increase in a driving voltage.

A hole transport layer (HTL) may be formed on the hole injection layer, for example, by using vacuum deposition, spin coating, casting, or LB. When the hole transport layer is formed by vacuum deposition or spin coating, the deposition or coating conditions may be similar to those applied to form the hole injection layer although the deposition or coating conditions may vary according to the material that is used to form the hole transport layer.

A material for the hole transport layer may be, for example, a suitable hole transport material. Examples of the hole transport material include a carbazole derivative, such as N-phenylcarbazole or polyvinylcarbazole, a triphenylamine-based material, such as N,N′-bis(3-methylphenyl)-N,N′-diphenyl-[1,1-biphenyl]-4,4′-diamine (TPD), N,N′-bis(naphthalen-2-yl)-N,N′-bis(phenyl)-benzidine (NPB), N,N′-bis(naphthalen-1-yl)-N,N′-bis(phenyl)-2,2′-dimethylbenzidine (α-NPD), and 4,4′,4″-tris(N-carbazolyptriphenylamine (TCTA).

A thickness of the hole transport layer may be in a range of about 50 Å to about 1,000 Å, for example, about 100 Å to about 800 Å. When the thickness of the hole transport layer is within the range described above, the hole transport layer may have satisfactory electron transport characteristics without a substantial increase in a driving voltage.

In some embodiments, instead of the hole injection layer and the hole transport layer, a hole injection and transport layer may be formed. The hole injection and transport layer may include at least one material selected from the materials for the hole injection layer and at least one material selected from the materials for the hole transport layer, and may have a thickness of about 500 Å to about 10,000 Å, and for example, about 100 Å to about 1,000 Å. When the thickness of the hole injection and transport layer is within these ranges, satisfactory hole injection and transport characteristics may be obtained without a substantial increase in driving voltage.

In addition, at least one layer of the hole injection layer, the hole transport layer, and the hole injection and transport layer may include at least one of a compound represented by Formula 100 below and a compound represented by Formula 101 below:

Ar₁₀₁ and Ar₁₀₂ in Formula 100 may be each independently a substituted or unsubstituted C₆-C₄₀ arylene group. In some embodiments, Ar₁₀₁ and Ar₁₀₂ may be each independently selected from a phenylene group, a pentalenylene group, an indenylene group, a naphthylene group, an azulenylene group, a substituted or unsubstituted an acenaphthylene group, a fluorenylene group, a phenalenylene group, a phenanthrenylene group, anthrylene group, a fluoranthenylene group, a triphenylenylene group, a pyrenylene group, a chrysenylenylene group, a naphthacenylene group, a picenylene group, a perylenylene group and a pentacenylene group; and a phenylene group, a pentalenylene group, an indenylene group, a naphthylene group, an azulenylene group, a substituted or unsubstituted an acenaphthylene group, a fluorenylene group, a phenalenylene group, a phenanthrenylene group, anthrylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof, a phosphoric acid or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₄₀ aryl group, a C₆-C₄₀ aryloxy group, a C₆-C₄₀ arylthio group, and a C₁-C₄₀ heteroaryl group.

a and b in Formula 100 may be each independently an integer selected from 0, 1, 2, 3, 4, and 5, or 0, 1, or 2. For example, a may be 1 and b may be 0.

R₁₀₁ to R₁₂₂ in Formulae 100 and 101 may be each independently selected from a hydrogen, a deuterium, a halogen atom, a hydroxyl group, a cyano group, a nitro group, an amino group, an amidino group, hydrazine, hydrazone, a carboxylic acid or a salt thereof, a sulfonic acid or a salt thereof, a phosphoric acid or a salt thereof a substituted or unsubstituted C₁-C₄₀ alkyl group, a substituted or unsubstituted C₂-C₄₀ alkenyl group, a substituted or unsubstituted C₂-C₄₀ alkynyl group, a substituted or unsubstituted C₁-C₄₀ alkoxy group, a substituted or unsubstituted C₃-C₄₀ cycloalkyl group, a substituted or unsubstituted C₆-C₄₀ aryl group, a substituted or unsubstituted C₆-C₄₀ aryloxy group, and a substituted or unsubstituted C₆-C₄₀ arylthio group.

For example, R₁₀₁ to R₁₀₈ and R₁₁₀ to R₁₂₂ may be each independently selected from a hydrogen, a deuterium, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₁₀ alkyl group (for example, a methyl group, an ethyl group, a propyl group, a butyl group, a pentyl group, or a hexyl group), a C₁-C₁₀ alkoxy group (for example, a methoxy group, an ethoxy group, a propoxy group, a butoxy group, or a pentoxy group), a phenyl group, a naphthyl group, an anthryl group, a fluorenyl group, and a pyrenyl group; a C₁-C₁₀ alkyl group, a C₁-C₁₀ alkoxy group, a phenyl group, a naphthyl group, an anthryl group, a fluorenyl group, and a pyrenyl group, each substituted with at least one of a deuterium, a halogen atom, a hydroxyl group, a cyano group, a nitro group, an amino group, an amidino group, a hydrazine group, a hydrazone group, a carboxylic acid or a salt thereof, a sulfonic acid or a salt thereof, and a phosphoric acid or a salt thereof.

R₁₀₉ in Formula 100 may be one selected from a phenyl group, a naphthyl group, an anthryl group, a biphenyl group, a pyridyl group; and a phenyl group, a naphthyl group, anthryl group, a biphenyl group and a pyridyl group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

According to an embodiment, the compound represented by Formula 100 may be represented by Formula 100A below:

R₁₀₈, R₁₀₉, R₁₁₇, and R₁₁₈ in Formula 100A may be understood by referring to the description provided herein.

For example, at least one layer of the hole injection layer, the hole transport layer, and the hole injection and transport layer may include at least one of Compounds 102 to 121 below.

At least one of the hole injection layer, the hole transport layer, and the hole injection and transport layer may further include a charge-generation material to increase conductivity of a layer, in addition to such known hole injection materials, known hole transport materials, and/or known materials having both hole injection and hole transport capabilities.

The charge-generation material may be, for example, a p-dopant. Examples of the p-dopant are a quinone derivative, such as tetracyanoquinodimethane (TCNQ) and tetrafluorotetracyanoquinodimethane (F4-TCNQ); a metal oxide, such as a tungsten oxide and a molybdenum oxide; and 1,4,5,8,9,11-hexaazatriphenylene-hexacarbonitrile (HATCN) illustrated below.

When the hole injection layer, the hole transport layer, and the hole injection and transport layer further include the charge-generation material, the charge-generation material may be homogeneously or unhomogeneously dispersed in the layers.

An emission layer (EML) may be formed on the hole transport layer or the hole injection and transport layer, for example, by spin coating, casting, or a LB method. When the emission layer is formed by vacuum deposition or spin coating, the deposition and coating conditions may be similar to those for the formation of the hole injection layer, though the conditions for deposition and coating may vary according to the material that is used to form the emission layer.

The emission layer may include a first host, a second host, and a dopant emitting delayed fluorescence.

For use as the first host, the compound represented by Formula 1 described in connection with the above embodiment of the emission layer may be used. For use as the second host, the compound represented by Formula 2-1, Formula 2-2, or Formula 3 described in connection with the above embodiment of the emission layer may be used. For use as the dopant emitting delayed fluorescence, the dopant compound described in connection with the above embodiment of the emission layer may be used.

In some embodiments, when the organic light-emitting device 10 constitutes a full-color display or a white light-emitting display, the emission layer may be patterned into a red emission layer, a green emission layer, and a blue emission layer in each subpixel, or may have a stack structure of a red emission layer, a green emission layer, and a blue emission layer.

In this regard, the blue emission layer may be the emission layer described above. That is, the blue emission layer may be the emission layer including the first host, the second host, and the delayed fluorescence dopant as described above.

In some embodiments, the red emission layer and the green emission layer may each include a suitable host and a suitable dopant. For example, a host in each of the red emission layer and the green emission layer may include at least one selected from TPBi, TBADN, ADN, CBP, CDBP, and TCP.

According to another embodiment, the host may include a compound represented by Formula 301 below.

Ar₃₀₁-[(L₃₀₁)_{xb1}-R₃₀₁]_{xb2} <Formula 301>

Ar₃₀₁ in Formula 301 may be selected from

a naphthalene, a heptalene, a fluorenene, a spiro-fluorene, a benzofluorene, a dibenzofluorene, a phenalene, a phenanthrene, an anthracene, a fluoranthene, a triphenylene, a pyrene, a chrysene, a naphthacene, a picene, a perylene, a pentaphene, and an indenoanthracene; and

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, a naphthacene, a picene, a perylene, a pentaphene, and an indenoanthracene, each substituted with at least one selected from a deuterium, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent C₂-C₆₀ non-aromatic condensed polycyclic group, and —Si(Q₃₀₁)(Q₃₀₂)(Q₃₀₃) (Q₃₀₁ to Q₃₀₃ are each independently selected from a hydrogen, a C₁-C₆₀ alkyl group, a C₂-C₆₀ alkenyl group, a C₆-C₆₀ aryl group, and a C₁-C₆₀ heteroaryl group);

L₃₀₁ may be understood by referring to the description provided in connection with L₂₀₁;

R₃₀₁ may be selected from

a C₁-C₂₀ alkyl group and a C₁-C₂₀ alkoxy group;

a C₁-C₂₀ alkyl group and a C₁-C₂₀ alkoxy group, each substituted with at least one of a deuterium, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazol group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one of a deuterium, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xb1 may be selected from 0, 1, 2, and 3;

xb2 may be selected from 1, 2, 3, and 4.

wherein in Formula 301,

L₃₀₁ may be selected from

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, and a chrysenylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, and a chrysenylene group, each substituted with at least one of a deuterium, a halogen atom a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group;

R₃₀₁ may be selected from

a C₁-C₂₀ alkyl and a C₁-C₂₀ alkoxy;

a C₁-C₂₀ alkyl group and a C₁-C₂₀ alkoxy group, each substituted with at least one of a deuterium, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group:

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group, each substituted with at least one of a deuterium, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group.

For example, the host may include a compound represented by Formula 301A below:

Substituents of Formula 301A may be understood by corresponding descriptions provided herein.

The compound represented by Formula 301 may include at least one of Compounds H1 to H42:

According to another embodiment, the host may include at least one of Compounds H43 to H49 below:

For a dopant in the red emission layer and the green emission layer, a suitable dopant may be used. The dopant may be at least one of a fluorescent dopant and a phosphorescent dopant. The phosphorescent dopant may be an organic metallic complex including Ir, Pt, Os, Re, Ti, Zr, Hf, or a combination of at least two of these.

Examples of a red dopant are Pt(II) octaethylporphine (PtOEP), tris(2-phenylisoquinoline)iridium (Ir(piq)₃), bis(2-(2′-benzothienyl)-pyridinato-N,C3′)iridium(acetylacetonate) (Btp2Ir(acac)), 4-(dicyanomethylene)-2-methyl-6[p-(dimethylamino)styryl]-4H-pyran (DCM), and 4-(dicyanomethylene)-2-tert-butyl-6-(1,1,7,7,-tetramethyljulolidyl-9-enyl)-4H-pyran (DCJTB).

Examples of a green dopant are tris(2-phenylpyridine) iridium (Ir(ppy)₃), bis(2-phenylpyridine)(acetylacetonato)iridium(III) (Ir(ppy)₂(acac)), tris(2-(4-tolyl)phenylpiridine)iridium (Ir(mppy)₃), and 10-(2-benzothiazolyl)-1,1,7,7-tetramethyl-2,3,6,7-tetrahydro-1H,5H,11H-[1]benzopyrano [6,7,8-ij]-quinolizin-11-one (C545T).

An amount of the dopant in the emission layer may be, for example, in a range of about 0.01 to about 15 parts by weight based on 100 parts by weight of the host.

A thickness of the emission layer may be in a range of about 100 Å to about 1,000 Å, for example, about 200 Å to about 600 Å. When the thickness of the emission layer is within this range, excellent light-emission characteristics may be obtained without a substantial increase in driving voltage.

A hole blocking layer (HBL) may be formed between the electron transport layer and the emission layer, for example, by vacuum deposition, spin coating, casting, LB deposition, or the like to prevent diffusion of excitons or holes into an electron transport layer. When the hole blocking layer is formed by vacuum deposition or spin coating, the deposition and coating conditions may be similar to those for the formation of the hole injection layer, though the conditions for deposition and coating may vary according to the material that is used to form the hole blocking layer. A hole blocking material may be, for example, an oxadiazole derivative, a triazole derivative, a phenanthroline derivative, and so on. For example, the hole blocking material may be 2,9-dimethyl-4,7-diphenyl-1,10-phenanthroline (BCP). In some embodiments, the first host or the second host used in the emission layer may also be used in the hole blocking layer.

A thickness of the hole blocking layer may be in a range of about 50 Å to about 1,000 Å, for example, about 100 Å to about 300 Å. When the thickness of the hole blocking layer is within these ranges, the hole blocking layer may have excellent hole blocking characteristics without a substantial increase in driving voltage.

In addition, an electron blocking layer (EBL) may be formed between the hole transport layer and the emission layer, for example, by vacuum deposition, spin coating, casting, LB deposition, or the like to prevent diffusion of excitons or electrons into the hole transport layer. In some embodiments, the first host or the second host used in the emission layer may also be used in the electron blocking layer.

An electron transport layer (ETL) may be formed on the emission layer by using various methods, for example, by vacuum deposition, spin coating, casting, or the like. When the electron transport layer is formed by vacuum deposition or spin coating, the vacuum deposition and coating conditions may be similar to those for the formation of the hole injection layer, though the conditions for vacuum deposition and coating may vary according to the material that is used to form the electron transport layer. A material for forming the electron transport layer may stably transport electrons injected from an electron injection electrode (cathode), and may be a known electron transport material.

Examples of the electron transportation material are a quinoline derivative, such as Alq₃, 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), BAlq (illustrated below), beryllium bis(benzoquinolin-10-olate) (Bebq2), 9,10-di(naphthalene-2-yl)anthracene (ADN), Compound 501, and Compound 502.

A thickness of the electron transport layer may be in a range of about 100 Å to about 1,000 Å, for example, about 150 Å to about 500 Å. When the thickness of the electron transport layer is within the range described above, the electron transport layer may have satisfactory electron transport characteristics without a substantial increase in a driving voltage.

In some embodiments, the electron transport layer may include an electron transport organic compound and a metal-containing material. The metal-containing material may include a Li complex. Examples of the Li complex are lithium quinolate (LiQ) and Compound 503 illustrated below:

An electron injection layer (EIL), which facilitates injection of electrons from the cathode, may be formed on the electron transport layer. A suitable electron injection material may be used to form the electron injection layer.

Examples of materials for forming the electron injection layer are LiF, NaCl, CsF, Li₂O, and BaO. The deposition conditions of the electron injection layer may be similar to those used to form the hole injection layer, although the deposition conditions may vary according to the material that is used to form the electron injection layer.

A thickness of the electron injection layer may be in a range of about 1 Å to about 100 Å, for example, about 3 Å to about 90 Å. When the thickness of the electron injection layer is within the range described above, the electron injection layer may have satisfactory electron injection characteristics without a substantial increase in a driving voltage.

The second electrode 17 is disposed on the organic layer 15. The second electrode may be a cathode that is an electron injection electrode, and in this regard, a metal for forming the second electrode may be a material having a low work function, and such a material may be metal, alloy, an electrically conductive compound, or a mixture thereof. For example, lithium (Li), magnesium (Mg), aluminum (Al), aluminum-lithium (Al—Li), calcium (Ca), magnesium-indium (Mg—In), or magnesium-silver (Mg—Ag) may be formed as a thin film to obtain a transmissive electrode. Also, to manufacture a top emission type light-emitting device, a transmissive electrode formed using ITO or IZO may be formed.

The C₁-C₂₀ alkyl group used herein may be a linear or branched C₁-C₂₀ alkyl group, and examples thereof are a methyl, an ethyl, a propyl, an isobutyl, a sec-butyl, a pentyl, an iso-amyl, and a hexyl. The C₁-C₂₀ alkoxy group used herein may be represented by —OA (A is an unsubstituted C₁-C₂₀ alkyl group described above), and examples thereof are a methoxy, an ethoxy, and an isopropyloxy.

The C₆-C₄₀ aryl group is a monovalent group having a carbocyclic aromatic system having 6 to 40 carbon atoms including at least one aromatic ring. The C₆-C₄₀ arylene group is a divalent group having a carbocyclic aromatic system having 6 to 40 carbon atoms including at least one aromatic ring. When the aryl group and the arylene group have at least two rings, they may be fused to each other.

Examples of the C₆-C₄₀ aryl group are a phenyl group, a C₁-C₁₀ alkylphenyl group (for example, an ethylphenyl group), a C₁-C₁₀ alkylbiphenyl group (for example, an ethylbiphenyl group), a halophenyl group (for example, an o-, m- or p-fluorophenyl group, or a dichlorophenyl group), a dicyanophenyl group, a trifluoromethoxyphenyl group, an o-, m-, or p-tolyl group, an o-, m-, or p-cumenyl group, a mesityl group, a phenoxyphenyl group, a (α,α-dimethylbenzene)phenyl group, a (N,N′-dimethyl)aminophenyl group, a (N,N′-a diphenyl)aminophenyl group, a pentalenyl group, an indenyl group, a naphthyl group, a halonaphthyl group (for example, a fluoronaphthyl group), a C₁-C₁₀ alkylnaphthyl group (for example, a methylnaphthyl group), a C₁-C₁₀ alkoxynaphthyl group (for example, a methoxy group a naphthyl group), an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylenyl group, a pyrenyl group, a chrysenyl group, an ethylchrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coroneryl group, a trinaphthylenyl group, a heptaphenyl group, a heptacenyl group, a pyranthrenyl group, and an ovalenyl group.

The C₁-C₄₀ heteroaryl group used herein refers to a monovalent group having a system composed of one or more aromatic rings having at least one hetero atom selected from nitrogen (N), oxygen (O), phosphorous (P), silicon (Si), and sulfur (S) and carbon atoms as the remaining ring atoms. The C₂-C₃₀ heteroarylene group used herein refers to a divalent group having a system composed of one or more aromatic rings having at least one hetero atom selected from nitrogen (N), oxygen (O), phosphorous (P), silicon (Si), and sulfur (S) and carbon atoms as the remaining ring atoms. In this regard, when the heteroaryl group and the heteroarylene group each include two or more rings, the rings may be fused to each other.

Examples of the C₁-C₄₀ heteroaryl group are a pyrazolyl group, an imidazolyl group, a oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, benzoan imidazolyl group, an imidazo pyridinyl group, and an imidazo pyrimidinyl group.

The C₆-C₄₀ aryloxy group used herein indicates —OA₂ (wherein A₂ is the substituted or unsubstituted C₆-C₃₀ aryl group), and a C₆-C₄₀ arylthio group indicates —SA₃ (wherein A₃ is the substituted or unsubstituted C₆-C₄₀ aryl group).

The first compound represented by Formula 1 and the second compound represented by Formula 2 may be synthesized by using a suitable organic synthetic method.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Hereinafter, an organic light-emitting device according to an embodiment will be described in detail with reference to Synthesis Examples and Examples. Compounds used in Examples are shown in Table 1 below.

TABLE 1

| | |
|---|---|
| h1 | |
| h2 | |
| h3 | |
| h4 | |
| h5 | |
| h6 | |
| D1 | |
| D2 | |

```
  α-NPD
  TCTA
  TPBI
```

### EXAMPLE 1

An anode was manufactured as follows: an ITO glass substrate (a product of Corning Co., Ltd) having an ITO layer of 15 Ω/cm² (thickness 1,200 Å) was cut to a size of 50 mm×50 mm×0.5 mm, and then sonicated by using acetone, isopropyl alcohol, and pure water each for 15 minutes, and cleaned by exposure to ultraviolet rays and ozone for 30 minutes. a-NPD was vacuum deposited on the ITO glass substrate to form a hole injection layer having a thickness of 600 Å, and then TCTA was vacuum deposited on the hole injection layer to form a hole transport layer having a thickness of 400Å. 70:30 weight ratio (Compound H1:Compound H2) of Compound H1 and Compound H2 as a host and Compound D1 as a blue dopant were co-deposited at a weight ratio (host:dopant) of 94:6 on the hole transport layer to form an emission layer having a thickness of 300 Å. TPBi was vacuum deposited on the emission layer to form an electron transport layer having a thickness of 300 Å. LiF was vacuum deposited on the electron transport layer to form an electron injection layer having a thickness of 10 Å, and then Al was vacuum deposited thereon to form a cathode having a thickness of 2,000 Å, thereby completing manufacturing of an organic light-emitting device.

### EXAMPLE 2

An organic light-emitting device was manufactured in the same manner as in Example 1, except that as the host of the emission layer, 90:10 weight ratio (Compound H1:Compound H3) of Compound H1 and Compound H3 were used instead of 70:30 weight ratio of Compound H1 and Compound H2.

### EXAMPLE 3

An organic light-emitting device was manufactured in the same manner as in Example 1, except that as the dopant of the emission layer, Compound D2 was used instead of Compound D1.

### EXAMPLE 4

An organic light-emitting device was manufactured in the same manner as in Example 2, except that as the dopant of the emission layer, Compound D2 was used instead of Compound D1.

### COMPARATIVE EXAMPLE 1

An organic light-emitting device was manufactured in the same manner as in Example 1, except that as the host of the emission layer, Compound H4 was used instead of 70:30 weight ratio of Compound H1 and Compound H2.

### COMPARATIVE EXAMPLE 2

An organic light-emitting device was manufactured in the same manner as in Example 1, except that as the host of the emission layer, Compound H5 was used instead of 70:30 weight ratio of Compound H1 and Compound H2.

### COMPARATIVE EXAMPLE 3

An organic light-emitting device was manufactured in the same manner as in Example 1, except that as the host of the emission layer, 90:10 weight ratio of Compound H6 and Compound H1 were used instead of 70:30 weight ratio of Compound H1 and Compound H2.

### COMPARATIVE EXAMPLE 4

An organic light-emitting device was manufactured in the same manner as in Comparative Example 1, except that as the dopant of the emission layer, Compound D2 was used instead of Compound D1.

### COMPARATIVE EXAMPLE 5

An organic light-emitting device was manufactured in the same manner as in Comparative Example 2, except that as the dopant of the emission layer, Compound D2 was used instead of Compound D1.

### COMPARATIVE EXAMPLE 6

An organic light-emitting device was manufactured in the same manner as in Comparative Example 3, except that as the dopant of the emission layer, Compound D2 was used instead of Compound D1.

### EVALUATION EXAMPLE

External quantum efficiency (EQE) of the organic light-emitting device manufactured according to Examples 1 to 4 and Comparative Examples 1 to 6 were evaluated at a current density of 0.1 mA/cm² and at a current density of 10 mA/cm^{2.} Results thereof are shown in Table 1 below.

TABLE 2

| | | | EQE | EQE |
|---|---|---|---|---|
| Device | Host | Dopant | (0.1 mA/cm²) | (10 mA/cm²) |
| Example 1 | H1:H2 (70:30) | D1 | 11.3% | 8.1% |
| Example 2 | H1:H3 (90:10) | D1 | 12.5% | 10.3% |
| Example 3 | H1:H2 (70:30) | D2 | 8.2% | 6.3% |
| Example 4 | H1:H3 (90:10) | D2 | 8.6% | 7.8% |
| Comparative | H4 | D1 | 4.1% | 2% |
| Example 1 | | | | |
| Comparative | H5 | D1 | 11% | 4.7% |
| Example 2 | | | | |
| Comparative | H6:H1 (90:10) | D1 | 10.8% | 6.5% |
| Example 3 | | | | |
| Comparative | H4 | D2 | 5.1% | 2.2% |
| Example 4 | | | | |
| Comparative | H5 | D2 | 7% | 5.3% |
| Example 5 | | | | |
| Comparative | H6:H1 (90:10) | D2 | 7.1% | 4.8% |
| Example 6 | | | | |

It was confirmed that at a current density of 0.1 mA/cm² and at a current density of 10 mA/cm², the external quantum efficiencies of the organic light-emitting devices of Examples 1 to 4 were all higher than those of the organic light-emitting devices of Comparative Examples 1 to 6. From these results, it was confirmed that efficiency and roll-off characteristics of the organic light-emitting devices of Examples 1 to 4 were higher than those of the organic light-emitting devices of Comparative Examples 1 to 6.

By way of summation and review, materials for forming the emission layer may include a fluorescent material using a singlet state (S1) and a phosphorescent material using a triplet state (T1), according to an emission mechanism. These luminescent materials are used alone or doped in a host material, and a statistical generation ratio of a singlet exciton to a triplet exciton in the emission layer is 1:3.

Besides fluorescent light emitted from a singlet excited state and phosphorescent light emitted from a triplet excited state, delayed fluorescence may be used in an organic light-emitting device. Delayed fluorescence refers to fluorescent emission made by activating an energy up-conversion from the excited triplet state to the excited singlet state with a thermal energy. Since the delayed fluorescence occurs after the energy up-conversion via triplet state, delayed fluorescence, for example, has a long lifespan.

For ease of the energy up-conversion from the triplet state to the singlet state, it is desirable for the luminescent material to have a smaller energy difference between the triplet state and the singlet state. Also, in converting as much triplet excited state as possible into the singlet excited state of a luminescent material, which acts as a dopant, the triplet energy level of a host material is also an important factor to be considered. However, in the case of a host material having a high triplet energy level, due to its great band gap energy, charges may not be effectively injected from adjacent layers, and due to its short conjugation length, electron transport characteristics may decrease.

As described above, embodiments may provide an organic light-emitting device including an emission layer emitting blue delayed fluorescence with high efficiency and improved roll-off characteristics.

An organic light-emitting device according to example embodiments may include an emission layer formed using a delayed fluorescent dopant and a mixed host. The organic light-emitting device including such an emission layer may have high efficiency and improved roll-off characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
a first electrode;
a second electrode facing the first electrode; and
an emission layer disposed between the first electrode and the second electrode and including a dopant, a first host, and a second host,
wherein the dopant is a material emitting delayed fluorescence, and
the first host includes a compound represented by Formula 1 below, and the second host includes any one of compounds represented by Formula 2-1, Formula 2-2, and Formula 3 below.
in Formula 1, Formula 2-1, Formula 2-2, and Formula 3,
X is N, S, or O, and when X is S or O, a₁ and a₂ are 0,
R₁ to R₃ are each independently selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof, a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group, —N(Q₁)(Q₂) (Q₁ and Q₂ are each independently a C₆-C₄₀ aryl group), a monovalent C₆-C₄₀ non-aromatic condensed polycyclic group;
a C₁-C₄₀ alkyl group, a C₂-C₄₀ alkenyl group, a C₂-C₄₀ alkynyl group, and a C₁-C₄₀ alkoxy group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group; and
a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a monovalent C₆-C₄₀ non-aromatic condensed polycyclic group, a C₆-C₄₀ aryloxy group, and a C₆-C₄₀ arylthio group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group,
a plurality of R₂ and R₃ are independent from each other,
Ar₁ to Ar₁₁ are each independently selected from —N(Q₁)(Q₂) (Q₁ and Q₂ are each independently a C₆-C₄₀ aryl group), a C₆-C₄₀ aryl group, a C₁-C₄₀ heteroaryl group, a monovalent C₆-C₄₀ non-aromatic condensed polycyclic group; —N(Q₁)(Q₂) (Q₁ and Q₂ are each independently a C₆-C₄₀ aryl group), a C₆-C₄₀ aryl group, a C₁-C₄₀ heteroaryl group, and a monovalent C₆-C₄₀ non-aromatic condensed polycyclic group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group,
L₁ to L₈ are each independently selected from a direct bond, —O—, a C₃-C₁₀ cycloalkylene group, a C₆-C₄₀ arylene group, a C₂-C₄₀ heteroarylene group, a divalent C₆-C₄₀ non-aromatic condensed polycyclic group; a C₃-C₁₀ cycloalkylene group, a C₆-C₄₀ arylene group, a C₂-C₄₀ heteroarylene group, and a divalent C₆-C₄₀ non-aromatic condensed polycyclic group, each substituted with at least one selected from a deuterium, a halogen atom, a hydroxyl group, a cyano group, a nitro group, an amino group, an amidino group, hydrazine, hydrazone, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₄₀ heteroaryl group, a C₆-C₄₀ aryloxy group, and a C₆-C₄₀ arylthio group,
a plurality of L₁ to L₈ are independent from each other, and when L₄ and L₅ are each a direct bond, Ar₃ and Ar₄ can be linked to each other to form a condensed cyclic ring,
a₁, b₁, and c₁ are an integer selected from 0, 1, 2, and 3,
a₂ is 0 or 1, and b₂ and c₂ are each 1 or 2,
b and c are each an integer selected from 0, 1, 2, 3, and 4, and
d to h are each independently an integer selected from 0, 1, 2, and 3.

2. The organic light-emitting device as claimed in claim 1, wherein:
R₁ to R₃ are each independently selected from a methyl group, an ethyl group, a propyl group, a butyl group, a pentyl group, a hexyl group, a heptyl group, a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran, an indolyl group, an isoindolyl group, an indolizinyl group, a benzofuryl group, an isobenzofuryl group, an indazolyl group, a benzimidazolyl group, a benzoxazolyl group, a benzisoxazolyl group, an imidazopyridyl group, a purinyl group, a quinolyl group, isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, a pyridoindolyl group, a dibenzofuryl group, a phenanthridinyl group, a benzoquinolyl group, a phenazinyl group, a dibenzosilolyl group, a dibenzothiophenyl group, a benzocarbazole group, —N(Q₁)(Q₂) (Q₁ and Q₂ are each independently a C₆-C₄₀ aryl group);
a methyl group, an ethyl group, a propyl group, a butyl group, a pentyl group, a hexyl group, a heptyl group, an octyl group, a nonyl group, and a decyl group, each substituted with at least one selected from a deuterium, a halogen atom, a hydroxyl group, a cyano group, a nitro group, and an amino group; and
a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran, an indolyl group, an isoindolyl group, an indolizinyl group, benzofuryl group, isobenzofuryl group, an indazolyl group, benzimidazolyl group, benzoxazolyl group, benzisoxazolyl group, imidazopyridyl group, a purinyl group, a quinolyl group, isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, pyridoindolyl group, dibenzofuryl group, a phenanthridinyl group, benzoquinolyl group, a phenazinyl group, a dibenzosilolyl group, a dibenzothiophenyl group, and a benzocarbazole group, each substituted with at least one selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₁₀ alkyl group, a C₂-C₁₀ alkenyl group, a C₂-C₁₀ alkynyl group, a C₁-C₁₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₃₀ aryl group, a C₁-C₃₀ heteroaryl group, a C₆-C₃₀ aryloxy group, a C₆-C₃₀ arylthio group and —Si(Q₃₁)(Q₃₂)(Q₃₃) (herein Q₃₁ to Q₃₃ are each independently selected from a hydrogen, a C₁-C₁₀ alkyl group, a C₁-C₁₀ alkoxy group, and a C₆-C₂₀ aryl group).

3. The organic light-emitting device as claimed in claim 1, wherein:
R₁ to R₃ are each independently selected from Formulae 4A to 4H below:
in Formulae 4A to 4H,
Z₁₁ to Z₁₆ are each independently selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, and a C₁-C₄₀ heteroaryl group;
a C₁-C₂₀ alkyl group and a C₁-C₂₀ alkoxy group, each substituted with at least one selected from a deuterium and a halogen atom; and
a C₆-C₄₀ aryl group and a C₁-C₆ heteroaryl group, each substituted with at least one selected from a deuterium, a halogen atom, a C₁-C₂₀ alkyl group, a C₁-C₂₀ alkoxy group, a C₆-C₂₀ aryl group, and a C₁-C₂₀ heteroaryl group;
p1 to p3 are each independently an integer selected from 0, 1, 2, 3, and 4, and
* indicates a binding site.

4. The organic light-emitting device as claimed in claim 3, wherein:
Z₁₁ to Z₁₆ each independently include a cyano group, a methyl group, an ethyl group, a t-butyl group, a phenyl group, or a naphthyl group.

5. The organic light-emitting device as claimed in claim 1, wherein:
R₁ to R₃ are each independently selected from Formulae 5A to 5J below:

6. The organic light-emitting device as claimed in claim 1, wherein:
L₁ to L₆ are each independently selected from —O—, cyclobutylene, adamantylene, phenylene, pentalenylene, indenylene, naphthylene, azulenylene, heptalenylene, indacenylene, acenaphthylene, fluorenylene, spiro-fluorenylene, benzofluorenylene, dibenzofluorenylene, phenalenylene, phenanthrenylene, anthracenylene, fluoranthenylene, triphenylenylene, pyrenylene, chrysenylene, naphthacenylene, picenylene, perylenylene, pentaphenylene, hexacenylene, pentacenylene, rubicenylene, coronenylene, ovalenylene, pyrrolylene, thiophenylene, furanylene, imidazolylene, pyrazolylene, thiazolylene, isothiazolylene, oxazolylene, isoxazolylene, pyridylene, pyrazinylene, pyrimidinylene, pyridazinylene, isoindolylene, indolylene, indazolylene, purinylene, quinolinylene, isoquinolinylene, benzoquinolinylene, phthalazinylene, naphthyridinylene, quinoxalinylene, quinazolinylene, cinnolinylene, carbazolylene, phenanthridinylene, acridinylene, phenanthrolinylene, phenazinylene, benzoimidazolylene, benzofuranylene, benzothiophenylene, isobenzothiazolylene, benzooxazolylene, isobenzooxazolylene, triazolylene, tetrazolylene, oxadiazolylene, triazinylene, dibenzofuranylene, dibenzothiophenylene, benzocarbazolylene, dibenzocarbazolylene, thiadiazolylene, and imidazopyridylene; and
phenylene, pentalenylene, indenylene, naphthylene, azulenylene, heptalenylene, indacenylene, acenaphthylene, fluorenylene, spiro-fluorenylene, benzofluorenylene, dibenzofluorenylene, phenalenylene, phenanthrenylene, anthracenylene, fluoranthenylene, triphenylenylene, pyrenylene, chrysenylene, naphthacenylene, picenylene, perylenylene, pentaphenylene, hexacenylene, pentacenylene, rubicenylene, coronenylene, ovalenylene, pyrrolylene, thiophenylene, furanylene, imidazolylene, pyrazolylene, thiazolylene, isothiazolylene, oxazolylene, isoxazolylene, pyridylene, pyrazinylene, pyrimidinylene, pyridazinylene, isoindolylene, indolylene, indazolylene, furinylene, quinolinylene, isoquinolinylene, benzoquinolinylene, phthalazinylene, naphthyridinylene, quinoxalinylene, quinazolinylene, cinnolinylene, carbazolylene, phenanthridinylene, acridinylene, phenanthrolinylene, phenazinylene, benzoimidazolylene, benzofuranylene, benzothiophenylene, isobenzothiazolylene, benzoxazolylene, isobenzoxazolylene, triazolylene, tetrazolylene, oxadiazolylene, triazinylene, dibenzofuranylene, dibenzothiophenylene, benzocarbazolylene, dibenzocarbazolylene, thiadiazolylene, and imidazopyridylene, each substituted with at least one selected from a deuterium, a halogen atom, a hydroxyl group, a cyano group, an amino group, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₁-C₆ heteroaryl group, a C₆-C₄₀ aryloxy group, and a C₆-C₄₀ arylthio group.

7. The organic light-emitting device as claimed in claim 1, wherein:
L₁ to L₆ are each independently selected from Formulae 6A to 6I below:
in Formulae 6A to 6I,
Z₂₁ to Z₃₀ are each independently selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, a C₁-C₄₀ heteroaryl group, a monovalent C₆-C₄₀ non-aromatic condensed polycyclic group, and Si(Q₃)(Q₄)(Q₅) (Q₃ to Q₅ are each independently a C₆-C₄₀ aryl group);
a C₁-C₂₀ alkyl group and a C₁-C₂₀ alkoxy group, each substituted with at least one selected from a deuterium and a halogen atom; and
a C₆-C₄₀ aryl group and a C₁-C₄₀ heteroaryl group, each substituted with at least one selected from a deuterium, a halogen atom, a C₁-C₂₀ alkyl group, a C₁-C₂₀ alkoxy group, a C₆-C₂₀ aryl group, and a C₁-C₂₀ heteroaryl group;
q1 is an integer selected from 0, 1, 2, 3, and 4;
q2 is an integer selected from 0, 1, 2, and 3;
q3 is an integer selected from 0, 1, and 2;
q4 and q5 are integers selected from 0, 1, 2, and 3;
q6 and q7 are integers selected from 0, 1, 2, 3, 4, and 5, and
* indicates a binding site.

8. The organic light-emitting device as claimed in claim 7, wherein:
Z₂₁ to Z₃₀ each independently include a methyl group, a triphenylsilyl group, or a triphenylmethyl group.

9. The organic light-emitting device as claimed in claim 1, wherein:
L₁ to L₆ are each independently selected from —O— and Formulae 7A to 7P below:
in the formulae above, * indicates a binding site.

10. The organic light-emitting device as claimed in claim 1, wherein:
Ar₁ to Ar₁₁ are each independently selected from a phenyl group, a pentalenyl group, an indenyl group, a naphthyl group, an azulenyl group, an indacenyl group, an acenaphthyl group, a biphenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyran, an indolyl group, an isoindolyl group, an indolizinyl group, benzofuryl group, isobenzofuryl group, an indazolyl group, a benzimidazolyl group, a benzoxazolyl group, a benzisoxazolyl group, an imidazopyridyl group, a purinyl group, a quinolyl group, an isoquinolyl group, a phthalazinyl group, a quinazolinyl group, a quinaxalinyl group, a naphthyridinyl group, a cinnolinyl group, a benzothiophenyl group, a benzothiazolyl group, a carbazolyl group, a benzocarbazolyl group, pyridoindolyl group, dibenzofuryl group, a phenanthridinyl group, a benzoquinolyl group, a phenazinyl group, a dibenzosilolyl group, a dibenzothiophenyl group, a benzocarbazole group;
a phenyl group, a pentalenyl group, an indenyl group, a naphthyl group, an azulenyl group, an indacenyl group, an acenaphthyl group, a biphenyl group, a phenalenyl group, a fluorenyl group, a phenanthrenyl group, an anthryl group, a fluoranthenyl group, a pyrenyl group, a benzofluorenyl group, a naphthacenyl group, a chrysenyl group, a triphenylenyl group, a terphenyl group, a perylenyl group, a picenyl group, a hexacenyl group, a spiro-fluorenyl group, a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyradazinyl group, a triazinyl group, a pyranyl group, a thiophenyl group, a thiazolyl group, an isothiazolyl group, a thiopyran, an indolyl group, an isoindolyl group, an indolizinyl group, benzofuryl group, isobenzofuryl group, an indazolyl group, a benzimidazolyl group, a benzoxazolyl group, a benzisoxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, pyridoindolyl group, dibenzofuryl group, a phenanthridinyl group, a benzoquinolyl group, a phenazinyl group, a dibenzosilolyl group, a dibenzothiophenyl group, and a benzocarbazole group, each substituted with at least one selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₁₀ alkyl group, a C₂-C₁₀ alkenyl group, a C₂-C₁₀ alkynyl group, a C₁-C₁₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₃₀ aryl group, a C₁-C₃₀ heteroaryl group, a C₆-C₃₀ aryloxy group, a C₆-C₃₀ arylthio group and —Si(Q₃₁)(Q₃₂)(Q₃₃) (herein, Q₃₁ to Q₃₃ are each independently selected from a hydrogen, a C₁-C₁₀ alkyl group, a C₁-C₂₀ alkoxy group, and a C₆-C₂₀ aryl group).

11. The organic light-emitting device as claimed in claim 1, wherein:
Ar₁ to Ar₁₁ are each independently selected from —N(Q₁)(Q₂) (Q₁ and Q₂ are each independently a C₆-C₄₀ aryl group), and Formulae 8A to 8H below:
in Formulae 8A to 8H,
Z₃₁ to Z₃₆ are each independently selected from a deuterium, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, a C₁-C₄₀ heteroaryl group, a monovalent C₆-C₄₀ non-aromatic condensed polycyclic group, and Si(Q₃)(Q₄)(Q₅) (Q₃ to Q₅ are each independently a C₆-C₄₀ aryl group);
a C₁-C₂₀ alkyl group and a C₁-C₂₀ alkoxy group, each substituted with at least one selected from a deuterium and a halogen atom; and
a C₆-C₄₀ aryl group and a C₁-C₄₀ heteroaryl group, each substituted with at least one selected from a deuterium, a halogen atom, a C₁-C₂₀ alkyl group, a C₁-C₂₀ alkoxy group, a C₆-C₂₀ aryl group, and a C₂₁-C₂₀ heteroaryl group;
r1 is an integer selected from 0, 1, 2, 3, 4, and 5,
r2 is an integer selected from 0, 1, 2, and 3,
r3 is an integer selected from 0, 1, 2, 3, and 4,
r4 is 0 or 2,
r5 is an integer selected from 0, 1, 2, 3, 4, and 5, and
* indicates a binding site.

12. The organic light-emitting device as claimed in claim 11, wherein:
Z₃₁ to Z₃₆ each independently include a methyl group, a t-butyl group, or a carbazolyl group.

13. The organic light-emitting device as claimed in claim 1, wherein:
Ar₁ to Ar₁ₗ are each independently selected from a diphenylamino group and Formulae 9A to 9J below:
in Formulae 9A to 9J, * indicates a binding site.

14. The organic light-emitting device as claimed in claim 1, wherein:
Formula 1 is represented by one of compounds illustrated below:

15. The organic light-emitting device as claimed in claim 1, wherein:
Formula 2-1 is represented by one of compounds illustrated below, and
Formula 2-2 is represented by one of compounds illustrated below:

16. The organic light-emitting device as claimed in claim 1, wherein:
Formula 3 is represented by one of compounds illustrated below:

17. The organic light-emitting device as claimed in claim 4, wherein:
a weight ratio of the first host to the second host is in a range of 10:90 to 90:10.

18. The organic light-emitting device as claimed in claim 1, wherein:
the dopant includes one of compounds represented by Formula 3-1 to Formula 3-4:
[EDG]ₘ-{Aₙ-[EWG]ₒ}ₚ <Formula 3-1>
[EWG]_{q}-{Aᵣ-[EDG]ₛ}ₜ <Formula 3-2>
[EWG]-A-[EDG]-B-[EWG] <Formula 3-3>
[EDG]-A-[EWG]-B-[EDG] <Formula 3-4>
wherein in Formulae 3-1 to 3-4,
EDG is an electron donating group and is —C═C—R, —O—R, —N(R)H, —N(R)₂, —NH₂, —OH, —NH(CO)—R, a substituted or unsubstituted C₁-C₂₀ aryl group, a C₆-C₃₀ aryl group, a substituted or unsubstituted monovalent C₆-C₃₀ non-aromatic condensed polycyclic group, a furanyl group or a derivative thereof, a benzofuranyl group or a derivative thereof, a dibenzofuranyl group or a derivative thereof, a thiophenyl group or a derivative thereof, a benzothiophenyl group or a derivative thereof, a dibenzothiophenyl group or a derivative thereof, a fluorenyl group or a derivative thereof, a spiro fluorenyl group or a derivative thereof, or an indenyl group or a derivative thereof,
EWG is an electron withdrawing group and is —X(—F, —Cl, —Br, —I), —C(═O)H, —C(═O)—R, —C(═O)O—R, —C(═O)OH, —(C═O)Cl, —CF₃, —S(═O)₂—OH, —S(═O)₂—O—R, —N⁺H₃, —N⁺R₃, —(N⁺═O)═O⁻, a C₂-C₃₀ substituted or unsubstituted N-containing 5-membered group, a C₂-C₃₀ substituted or unsubstituted N-containing 6-membered group, a substituted or unsubstituted N-containing 5-membered group to which a C₁₀-C₃₀ 6-membered ring is fused, or a substituted or unsubstituted N-containing 6-membered group to which a C₁₀-C₃₀ 6-membered ring is fused,
R is independently a hydrogen, a deuterium, a C₆-C₃₀ aryl group, a C₁-C₃₀ heteroaryl group; a C₆-C₃₀ aryl group or a C₁-C₃₀ heteroaryl group, each substituted with at least one selected from a C₁-C₁₀ alkyl group, a C₁-C₁₀ alkoxy group, a C₆-C₃₀ aryl group, a C₁-C₃₀ heteroaryl group, a C₆-C₃₀ aryloxy group, or a C₆-C₃₀ arylthio group,
A and B are linking groups that link an EDG to an EWG, and is a single bond, a C₁-C₃₀ alkylene, or a C₆-C₃₀ arylene group, and
m, q, o, s, p, and t are an integer selected from 1, 2, 3, 4, 5, 6, 7, 8, 9, and 10, and n and r are 0 or 1.

19. The organic light-emitting device as claimed in claim 1, wherein:
the dopant includes one of compounds illustrated below:

20. The organic light-emitting device as claimed in claim 1, further comprising:
a hole transport region disposed between the first electrode and the emission layer, and an electron transport region between the second electrode and the emission layer.
